(19) United States
(12) Patent Application Publication
(10) Pub. No.: US 2020/0346777 A1
(43) Pub. Date: Nov. 5, 2020

(54) FUSELAGE AND UNMANNED AERIAL VEHICLE THEREOF

(71) Applicant: SZ DJI TECHNOLOGY CO., LTD., Shenzhen (CN)

(72) Inventors: Zhao TONG, Shenzhen (CN); Jiangang FENG, Shenzhen (CN); Yin TANG, Shenzhen (CN); Yumian DENG, Shenzhen (CN)

(21) Appl. No.: 16/932,497

(22) Filed: Jul. 17, 2020

Related U.S. Application Data
(63) Continuation of application No. PCT/CN2018/073512, filed on Jan. 19, 2018.

(51) Int. Cl. B64D 31/00; H05K 7/20; B64C 39/02; B64C 19/00; B64D 47/08; B64C 25/40

(52) U.S. Cl. CPC B64D 31/00; H05K 7/20863; H05K 7/20172; B64C 39/02; B64C 2201/145; B64D 47/08; B64C 25/40; B64C 2201/027; B64C 19/00

(57) ABSTRACT

The present disclosure provides an Unmanned Ariel Vehicle (UAV). The UAV includes a fuselage including a housing, a core control board disposed in the housing, and a battery, the housing including a battery compartment, and the battery being disposed in the battery compartment; an arm disposed on the fuselage; and a power assembly disposed on the arm. The core control board is disposed above the battery, a payload receiving cavity is disposed at a front lower end of the housing, a rear-bottom view component is disposed at a rear end of the housing and electrically connected to the core control board, and the battery compartment is disposed at a middle position under the housing.

### CROSS-REFERENCE TO RELATED APPLICATION

This application is a continuation of International Application No. PCT/CN2018/073512, filed on Jan. 19, 2018, the entire content of which is incorporated herein by reference.

### TECHNICAL FIELD

The present disclosure relates to the field of unmanned aerial vehicles and, more specifically, to a fuselage and an unmanned aerial vehicle (UAV).

### BACKGROUND

The assembly position of the battery of the UAV is located above the fuselage, and the battery can be assembled into the fuselage from the top of the fuselage. However, the battery weight of the UAV is relatively heavy, generally accounting for substantially one third of the weight of the UAV. By placing the battery above the fuselage, the center of gravity of the UAV is relatively high, therefore, it is difficult to ensure the flight stability of the UAV.

### SUMMARY

The present disclosure provides an UAV. The UAV includes a fuselage including a housing, a core control board disposed in the housing, and a battery, the housing including a battery compartment, and the battery being disposed in the battery compartment; an arm disposed on the fuselage; and a power assembly disposed on the arm. The core control board is disposed above the battery, a payload receiving cavity is disposed at a front lower end of the housing, a rear-bottom view component is disposed at a rear end of the housing and electrically connected to the core control board, and the battery compartment is disposed at a middle position under the housing.

### BRIEF DESCRIPTION OF THE DRAWINGS

In order to illustrate the technical solutions in accordance with the embodiments of the present disclosure more clearly, the accompanying drawings to be used for describing the embodiments are introduced briefly in the following. It is apparent that the accompanying drawings in the following description are only some embodiments of the present disclosure. Persons of ordinary skill in the art can obtain other accompanying drawings in accordance with the accompanying drawings without any creative efforts.

FIG. 1 is a perspective view of a UAV according to an embodiment of the present disclosure.

FIG. 2 is an exploded perspective view a fuselage of the UAV shown in FIG. 1.

FIG. 3 is an exploded perspective view of the fuselage shown in FIG. 2 from another perspective.

FIG. 4 is a partial cross-sectional view at the position of a landing gear of the UAV shown in FIG. 1.

### DETAILED DESCRIPTION OF THE EMBODIMENTS

Technical solutions of the present disclosure will be described in detail with reference to the drawings. It will be appreciated that the described embodiments represent some, rather than all, of the embodiments of the present disclosure. Other embodiments conceived or derived by those having ordinary skills in the art based on the described embodiments without inventive efforts should fall within the scope of the present disclosure.

Reference will now be made in detail to exemplary aspects of the present disclosure, examples of which are illustrated in the accompanying drawings. The following description refers to the accompanying drawings in which the same numbers in different drawings represent the same or similar elements unless otherwise represented. The implementations set forth in the following description of exemplary aspects do not represent all implementations consistent with the present disclosure. Instead, they are merely examples of apparatuses and methods consistent with aspects related to the present disclosure as recited in the appended claims.

The terminologies used herein are only for describing particular aspects but not for limiting the present disclosure. The singular form words “a,” “the,” and “said” used in the present disclosure and append claims are intended to include plural form, unless otherwise clearly stated. In addition, it shall be appreciated that the terminology “and/or” used herein refers to any or all combinations of one or more listed related items.

The fuselage and the UAV of the present disclosure will be described in detail below with reference to the drawings. The features in the following examples and embodiments can be combined with each other when there is no conflict.

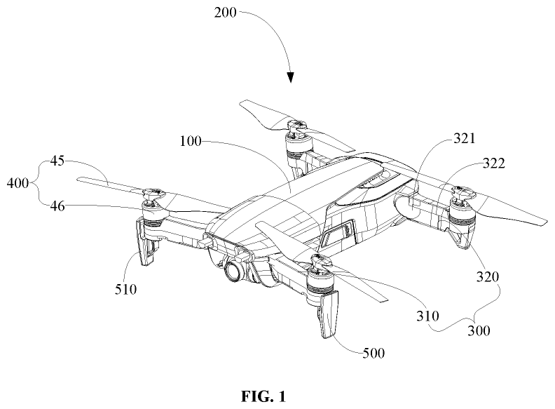

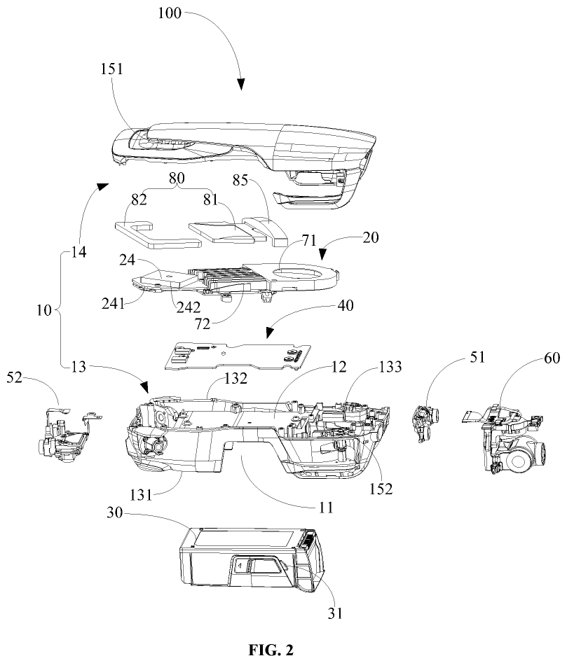

Referring to FIGS. 1-3, a UAV 200 can be used for aerial photography, mapping, monitoring, but is not limited thereto. In some embodiments, the UAV can also be used for agriculture, express delivery, and providing network services. In the present embodiment, the UAV 200 includes a fuselage 100, an arm 300 disposed on the fuselage 100, a power assembly 400 disposed on the arm 300, and a landing gear 500.

The power assembly 400 may include a rotor 45 and a motor 46. The rotor 45 may be driven to rotate by the motor 46, thereby providing power for the lift, advancement, rotation, etc. of the UAV 100. The rotor 45 may include a blade and a hub, the hub may be fixed to an output shaft of the motor, and the blade may be mounted on the hub.

The fuselage 100 may include a housing 10, a core control board 20 disposed in the housing 10, and a battery 30. A battery compartment 11 may be disposed in the housing, and the battery may be disposed in the battery compartment 11.

The core control board 20 may be positioned above the battery 30, and payload receiving cavity 16 may be disposed at the front lower end of the housing. A rear-bottom view component 52 may be disposed in the rear of the housing 10. The rear-bottom view component 52 may be electrically connected to the core control board 20, and the battery compartment 11 may be disposed at a middle position under the housing 10. Since the weight of the battery is relatively heavy, the center of gravity of the UAV 200 can be centered and lowered, which can improve the flight stability of the UAV.

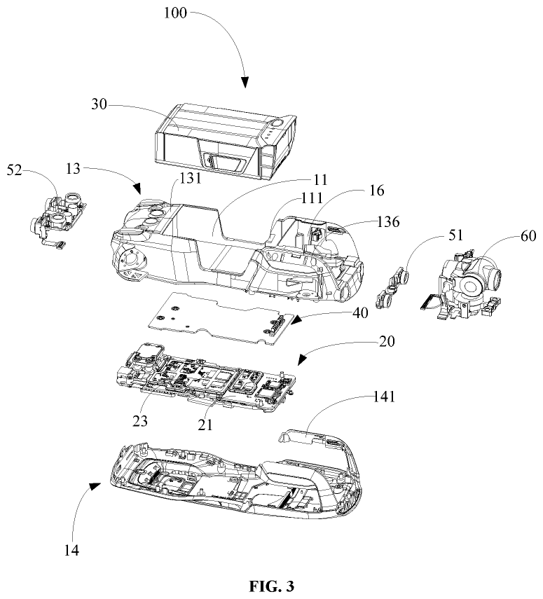

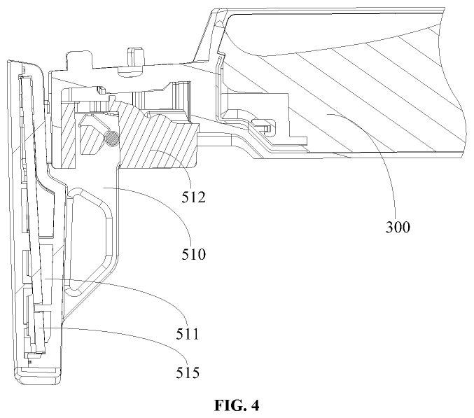

In the illustrated embodiment, the battery compartment 11 is recessed from a bottom surface 131 of the housing 10, and the battery 30 is mounted in the battery compartment 11 through a locking structure. Referring to FIGS. 3-4. More specifically, the locking structure may include a locking pin 31 slidably disposed on both sides of the battery, a locking groove 111 disposed at a corresponding position on an inner wall of the battery compartment 11, and an elastic member (not shown) at one end of the lock pin 31. When the battery 30 is mounted in the battery compartment 11 of the housing 10, the elastic member can push the locking pin 31 to make the locking pin 31 snap in to the locking groove 111, thereby fixing the battery 30 in the battery compartment 11. Of course, in other embodiments, the locking structuring may also include other structures, which is not limited herein.

Still referring to FIGS. 3-4. The housing 10 may include a housing body 13 and a cover 14. The housing body 13 may include a top surface 132 opposite to the bottom surface 131. A receiving cavity 12 may be disposed on the top surface 132 for receiving the core control board 20, and the cover 14 may be used to close the core control board 20 in the receiving cavity 12. In some embodiments, a protrusion 141 that extends to the bottom of the housing body 13 may be disposed on the cover 14. Correspondingly, a recess 136 may be provided on the housing body 13 to cooperate with the protrusion 141. As such, the cover 14 and the housing body 13 may be connected with each other, thereby increasing the strength of the UAV 200.

The core control board 20 may be electrically connected to each functional module of the UAV 200 and coordinates the work of each functional module. In the illustrated embodiment, the core control board 20 is positioned between the battery 30 and the cover 14, that is, in the middle of the fuselage 100. As such, the distance between the core control board 20 and each functional module is reduced, thereby reducing the internal wiring and optimizing the internal space arrangement of the UVA 200.

The fuselage may also include an electronic speed control board 40. The electronic speed control board 40 may be configured to control the operation of the motor. The electronic speed control board 40 may be electrically connected to the core control board 20 to control the start and stop, the rotational speed, the steering, etc. of the motor based on the control signal sent by the core control board 20, thereby controlling the flight direction and flight speed of the UAV 200. In the illustrated embodiment, the electronic speed control board 40 is disposed at the bottom of the receiving cavity 12, and the core control board 20 is disposed above the electronic speed control board 40. Therefore, as the core components of the UAV 200, the electronic speed control board 40 and the core control board 20 may be both positioned in the middle of the fuselage 100. When the UAV 200 receives an impact, the UAV 200 cannot be easily damaged.

In some embodiments, the fuselage 100 may further include a front view assembly 51 electrically connected to the core control board 20. The front view assembly 51 may be disposed at the front of the housing 10. The front view assembly 51 may be used to detect obstacles in front of the UAV 200, and send the detection data to the core control board 20. The rear-bottom view assembly 52 describe above may be used to detect obstacles behind and below the UAV 200, and send the detection data to the core control board 20.

In some embodiments, the front view assembly 51 and the rear-bottom view assembly 52 may be positioned blow the core control board 20, which can further lower the center of gravity of the UAV 200 and improve flight stability. In other embodiments, the front view assembly 51 and the rear-bottom view assembly 52 may be positioned at other positions, such as at the same height as the core control board 20, but is not limited thereto.

In some embodiments, the front view assembly 51 and the rear-bottom view assembly 52 may be respectively connected to the core control board 20 through a flexible circuit board, but is not limited thereto.

In some embodiments, the fuselage 100 may further include a payload 60 electrically connected the core control board 20, and the payload 60 may be disposed in the payload receiving cavity 16.

In some embodiments, the payload 60 may be positioned below the core control board 20, which can further lower the center of gravity of the UAV 200 and improve flight stability. In other embodiments, the payload 60 may be positioned at other positions, such as at the same height as the core control board 20, but is not limited thereto.

In some embodiments, the payload 60 may include a gimbal and an imaging device carried on the gimbal, and the payload 60 may be connected to the core control board 20 through a flexible circuit board.

In some embodiments, the core control board 20 may include a board fuselage 21, and a circuit assembly 23 disposed on the board fuselage 21. The circuit assembly 23 may include a flight control module, a vision module, and an imaging module.

The flight control module is the core component of the UAV 200. The flight control module can be used to control the main functions of the UAV 200 as the central controller of the UAV 200. For example, the flight control module can be used to manage the working mode of the control system of the UAV 200, perform calculation on the data sent by the vision module, the imaging module, and various sensors to the flight control module and generate control signals, manage various sensors and servo systems in the UAV 200, control and perform data exchange of other tasks and electronic components in the UAV 200, receive ground commands to control the flight actions of the UAV and acquire the attitude information of the UAV 200, etc.

The vision module can be used to process the visual image data from the image sensor based on a certain computer vision algorithm, and send the processing results to the flight control module for the flight control module to make obstacle avoidance or navigation decisions.

The imaging module can be used to process the aerial image data from the image sensor based on different needs by using the corresponding algorithm to meet the subsequent storage or transmission needs, and can simultaneously output multiple channels of data to meet different needs.

In some embodiments, the core control board 20 may further include a positioning module 24. In the illustrated embodiment, the positioning module 24 is a GPS module. The GPS module is positioned on the side of the core control board 20 away from the battery compartment 11. In other embodiments, the positioning module 24 can also be other modules, such as the Beidou positioning module, etc., which is not limited thereto.

In some embodiments, the core control board 20 may further include a gimbal control module. The gimbal may be connected to the gimbal control module, and the gimbal control module may be electrically connected to the flight control module to facilitate communication between the gimbal and the flight control module to control and drive the gimbal. In some embodiments, the gimbal can be connected to the gimbal control module through a flexible circuit board.

In order to dissipate heat from the electronic components on the core control board 20, the fuselage may further include a heat dissipation structure. The heat dissipation structure will be described below.

A first air outlet 151 and a second air outlet 152 for heat dissipation of the core control board 20 may be disposed on the housing 10. The first air outlet 151 may be used introduce the airflow outside the fuselage from the first air outlet 151 into the housing, and the second air outlet 152 may be used direct the airflow out of the housing 10 after heat transfer is performed with the core control board 20. In some embodiments, the side projection of the first air outlet 151 may at least partially overlap with the side projection of the rotor 45. The direction of the side projection mentioned above may refer to the side direction of the fuselage. It can be understood that direction of the side projection mentioned above may refer to the direction of the side of the fuselage of the UAV. That is, when projecting on the fuselage side of the UAV, the projection of the first air outlet 151 and the projection of the rotor 45 may at least partially overlap.

During the flight of the UVA, the rotation of the rotor 45 can form a plane of rotation. On one hand, the rotation of the rotor 45 may cause the surrounding air to move in the direction of rotation of the rotor 45. A part of the airflow around the rotor 45 may be detached from the surface of the rotor 45 and run along the tangential direction of the plane of rotation due to air resistance. On another hand, the air around the rotor 45 may also be directed below the plane of rotation to form downwash airflow. Since the side projection of the first air outlet 151 at least partially overlaps with the side projection of the rotor 45, based on the design, the airflow running along the tangential direction of the plane of rotation, and/or the downwash airflow running along the plane of rotation may enter the housing 10 through the first air outlet 151. The UAV generally flies at a relatively high altitude, and the temperature of the surrounding air is generally low. Therefore, the low temperature airflow entering the housing 10 from the first air outlet 151 may can play a good role in cooling and heat dissipation of the core control board 20 without increasing the noise of the UAV 200.

In the illustrated embodiment, the first air outlet 151 is disposed on the cover 14. Based on the rotor 45 and other height designs on the top of the UAV 200, the first air outlet 151 may also be disposed on the sidewall of the UAV 200, which is no limited herein.

In some embodiments, the fuselage 100 may also include a heat dissipation assembly for active heat dissipation. The heat dissipation assembly may disposed on the core control board 20 and may include a cooling fan 71 and a plurality of heat dissipation fins 72. The cooling fan 71 may be disposed near the second air outlet 152, and may be used to draw airflow into the fuselage through the second air outlet 152. The plurality of heat dissipation fins 72 may be disposed near the second air outlet 152. The airflow may flow through the plurality of heat dissipation fins 72 and discharge through the second air outlet 152. For better cooling, the core control board 20 may further include a split flow module. The split flow module may split the cooling airflow, such that the cooling airflow can be discharged from the fuselage more effectively.

In some embodiments, the positioning module 24 disposed on the core control board 20 may be near the first air outlet 151, and may be used to distribute and guide the passing cooling airflow (the cooling airflow may be the airflow generated when the rotor 45 rotates, or the airflow generated when the cooling fan 71 rotates), which can effectively discharge the cooling airflow out of the housing 10 from multiple directions. Of course, the cooling airflow can also be guided by other modules or structures.

In some embodiments, the positioning module 24 may include a first part 241, and a second part 242 disposed on the first part 241. The first part 241 and the second part 242 may cooperate to guide the airflow. The second part 242 may be a square structure, and the corners of the square structure may be respectively near the sides of the first part 241. That is, a pair of adjacent sides of the second part 242 may cooperate with the first part 241, and a 45° airflow direction may be formed from one side of the first part 241 to the adjacent two sides and form an airflow direction above the second part 242. As such, the cooling airflow passing through the positioning module 24 may be split into three airflow directions. Therefore, the extension direction of the two adjacent side surfaces of the square structure may correspond to the direction of the corresponding first air outlet 151, such that heat can be dissipated more efficiently. Of course, the second part 242 may also have other shapes, such as a diamond-shaped structure, etc. As long as the second part 242 has a structure that can divide the guide the cooling airflow, the second part 242 is not limited to a specific shape.

In some embodiments, the heat dissipation assembly may include a windshield 80. The windshield 80 may be used to form a closed air passage from the heat dissipation fins 72 to the first air outlet 151. The windshield 80 may include a first part 81 and a second part 82. The first part 81 may cover the plurality of heat dissipation fins 72 and close the top of the heat dissipation fins 72. The second part 82 may have a U-shaped structure, surrounding a side of the positioning module 24 away from the plurality of heat dissipation fins 72 and its adjacent sides. As such, the cooling airflow can be limited to the closed air duct, and discharged from the first air outlet 151, or the first air outlet 151 and the second air outlet 152 out of the housing 10 to prevent the cooling airflow from spreading to other parts of the housing 10, thereby improving the cooling efficiency of the electronic components. A windshield protrusion 85 may also be disposed between the cooling fan 71 and the plurality of heat dissipation fins 72. The material of the windshield protrusion 85 may include, but is not limited to foam. An opening may be disposed on the windshield protrusion 85 corresponding to the air outlet of the cooling fan 71, and the opening may communicate with the plurality of cooling channels formed by the plurality of heat dissipation fins 72. The windshield protrusion 85 can separate cold air from the outside and the hot air after heat transfer, thereby improving the cooling efficiency of the cooling fan 71.

In some embodiments, the heat dissipation assembly may be fixed on the core control board 20, and disposed on both sides of the core control board 20 opposite to the circuit assembly 23.

The heat dissipation structure described above can cool the core control board 20 and other electronic components in the fuselage through a variety of cooling methods. When the UAV is in flight, the airflow generated by the rotation of the rotor is mainly used for cooling. The airflow may enter the housing 10 from the first air outlet 151, exchange heat with electronic components, and discharge through the second air outlet 152. At this time, the cooling fan 71 can be turned on to improve the cooling efficiency, or the cooling fan 71 can be turned off. When the UAV is in a standby state (that is, the UAV is powered on, but not yet in flight), the cooling fan 71 can be turned on to drive the airflow from the second air outlet 152 into the housing 10. After the airflow exchanges heat with the electronic components, the airflow may be discharges through the first air outlet 151.

In some embodiments, the arm 300 may be a foldable arm, which is convenient for transportation and storage.

In addition, the arm 300 may include a pair first arms 310 disposed at one end of the fuselage and a pair of second arms 320 disposed at the other end of the fuselage. The first arm 310 may rotate relative to the fuselage until the first arm 310 are collapsed outside the fuselage. The second arm 320 may include a connecting arm 321 that ma rotate relative to the fuselage and a support arm 322 that may rotate relative to the length direction of the connecting arm 321. By rotating the support arm 322 to a certain angle and the rotating the connecting arm 321, the second arm 320 may be collapsed outside the fuselage, and the rotor 45 and the motor 46 of the first arm 310 may face upward. Therefore, the interference between the rotor of the first arm 310 and the rotor of the second arm 320 may be avoided after the arm 300 is folded. In some embodiments, the first arm 310 may be disposed at the front of the fuselage, and the second arm 320 may be disposed at the rear of the fuselage. In other embodiments, the first arm 310 may be disposed at the rear of the fuselage, and the second arm 320 may be disposed at the front of the fuselage.

In the illustrated embodiment, the length of the first arm 310 and the length of the second arm 320 may not exceed the length of the fuselage. As such, the first arm 310 and the second arm 320 may not interfere after being folded. In addition, the first arm 310 and the second arm 320 may be disposed at substantially the same height or different heights of the fuselage.

Referring to FIG. 4, the UAV 200 furthers include a landing gear 500 having a folded state and an open state. The landing gear 500 may include a bracket 512 connected to the arm 300, and a leg 510 rotatably connected to the bracket 512. When the leg 510 is perpendicular to the arm, the landing gear 500 may be in an open state, and when the leg 510 is parallel to the arm, the landing gear 500 may be in a folded state. During storage and transportation, the leg 510 can be turned first to make the landing gear 500 in the folded state, and then the arm 300 can be folded.

The landing gear 500 may further include an antenna board 515. A receiving cavity 511 may be disposed on the leg 510 for receiving and fixing the antenna board 515. When the leg 510 is rotated, the antenna board 515 may rotate accordingly. The antenna board 515 may be connected to the core control board 20 through an antenna. The antenna board 515 may receive the wireless communication signal and provide the wireless communication signal to the core control board 20. Since the antenna board 515 is disposed in the leg 510, the wireless communication signal of the remote control other control terminal generally comes from the ground (i.e., the wireless communication signal is generally transmitted from below the UAV to the UAV), as such, by disposing the antenna board 515 in the leg 510 below the UAV, it may be more convenient and efficient to receive the wireless communication signal.

In the present embodiment, the landing gear 500 is only disposed on the pair of first arms 310 disposed at the front of the fuselage to raise the gimbal. As such, when the gimbal is performing self-check on the impact limit during takeoff, the imaging device carried on the gimbal may not touch the ground. Of course, in other embodiments, the landing gear 500 may also be disposed on the pair of second arms 320 at the rear of the fuselage based on the actual needs, or the landing gear 500 may be disposed on both pairs of arms.

It should be noted that the relationship terms used in the text of this application, such as first and second, are only for distinguishing an object or operation from another object or operation, but not for defining or implying any practical relation or order between the object or operation. The terms “include”, “contain” or other alternatives shall be non-exclusiveness, the inclusion of a series of element such as process, method, object or equipment shall include not only the already mentioned elements but also those elements not mentioned, and shall include the elements which are inherent in the process, method, object or equipment. However, under the condition of no more limitations, the definition of an essential element limited by the sentence “including a . . . ” shall not obviate that in addition to containing the said essential element in the process, method, object or equipment, other essential element of the same nature may also exist in the above-mentioned process, method, object or equipment.

The method and device provided in embodiments of the present disclosure have been described in detail above. In the present disclosure, particular examples are used to explain the principle and embodiments of the present disclosure, and the above description of embodiments is merely intended to facilitate understanding the methods in the embodiments of the disclosure and concept thereof; meanwhile, it is apparent to persons skilled in the art that changes can be made to the particular implementation and application scope of the present disclosure based on the concept of the embodiments of the disclosure, in view of the above, the contents of the specification shall not be considered as a limitation to the present disclosure.

What is claimed is:

1. An Unmanned Ariel Vehicle (UAV), comprising:
a fuselage including a housing, a core control board disposed in the housing, and a battery, the housing including a battery compartment, and the battery being disposed in the battery compartment;
an arm disposed on the fuselage; and
a power assembly disposed on the arm, wherein
the core control board is disposed above the battery, a payload receiving cavity is disposed at a front lower end of the housing, a rear-bottom view component is disposed at a rear end of the housing and electrically connected to the core control board, and the battery compartment is disposed at a middle position under the housing.

2. The UAV of claim 1, wherein:
the battery compartment is recessed from a bottom surface of the housing, and the battery is disposed in the battery compartment through a locking structure.

3. The UAV of claim 2, wherein:
the housing includes a housing body and a cover, the housing body including a top surface opposite to the bottom surface, the top surface including a receiving cavity for receiving the core control board, and the cover enclosing the core control board in the receiving cavity.

4. The UAV of claim 3, wherein:
the cover includes a protrusion extending to a position of the bottom of the housing body, and the housing body includes a corresponding recess cooperating with the protrusion.

5. The UAV of claim 3, further comprising:
an electronic speed control board disposed at the bottom of the receiving cavity, the core control board being disposed above the electronic speed control board.

6. The UAV of claim 1, further comprising:
a front view component being electrical connected to the core control board, the front view component being disposed at a front of the housing.

7. The UAV of claim 6, wherein:
the front view component and the rear-bottom view component are disposed below the core control board.

8. The UAV of claim 6, wherein:
the front view component and the rear-bottom view component are connected to the core control board through a flexible circuit board.

9. The UAV of claim 1, further comprising:
a payload being disposed in the payload receiving cavity and below the core control board, and electrically connected to the core control board.

10. The UAV of claim 9, wherein:
the payload includes a gimbal and an imaging device carried on the gimbal, and the payload is electrically connected to the core control board through a flexible circuit board.

11. The UAV of claim 1, wherein:
the core control board includes a board fuselage and a circuit assembly disposed on the board fuselage.

12. The UAV of claim 11, wherein:
the circuit assembly includes a flight control module and a vision module.

13. The UAV of claim 11, wherein:
the core control board further includes a positioning module including a GPS module, the GPS module being disposed on a side of the core control board away from the battery compartment.

14. The UAV of claim 1, further comprising:
a first air outlet and a second air outlet disposed on the housing for cooling the core control board; wherein
the first air outlet introducing airflow outside the fuselage from the first air outlet into the housing, and the second air outlet discharging the airflow out of the housing after heat transfer with the core control board.

15. The UAV of claim 14, further comprising:
a heat dissipation assembly including a cooling fan disposed near the first air outlet to draw the airflow into the fuselage through the first air outlet, and a plurality of heat dissipation fins disposed near the second air outlet to discharge the airflow flowing through the plurality of heat dissipation fins through the second air outlet.

16. The UAV of claim 14, wherein:
the core control board further includes a positioning module disposed near the first air outlet, and the positioning module includes a first part and a second part disposed in the first part, the first part and the second part cooperate to guide the airflow.

17. The UAV of claim 15, wherein:
the heat dissipation assembly is fixed on the core control board, and is disposed on both sides of the core control board opposite to the circuit assembly.

18. The UAV of claim 1, wherein:
the arm includes a pair of first arms disposed at one end of the fuselage and a pair of second arms disposed at the other end of the fuselage, the first arm being rotatable relative to the fuselage until the first arm is collapsed outside the fuselage, and the second arms including a connecting arm rotatable relative to the fuselage and a support arm rotatable relative to the length of the connecting arm; and
the support arm is rotated to an angle, and the first arm is rotated to collapse the second arm outside the fuselage.

19. The UAV of claim 18, wherein:
a sum of the length of the first arm and the length of the second arm does not exceed the length of the fuselage.

20. The UAV of claim 1, further comprising:
a landing gear having a folded state and an open state, the landing gear including a bracket connected to the arm and a leg rotatably connected to the bracket, wherein the landing gear is in the open state when the leg is perpendicular to the arm, and the landing gear is in the folded state when the leg is parallel to the arm.
